(19) United States
(12) Patent Application Publication
(10) Pub. No.: US 2020/0379246 A1
(43) Pub. Date: Dec. 3, 2020

(54) OPTICAL MODULE FOR ENDOSCOPE, ENDOSCOPE, AND MANUFACTURING METHOD OF OPTICAL MODULE FOR ENDOSCOPE

(71) Applicant: OLYMPUS CORPORATION, Tokyo (JP)

(72) Inventor: Kosuke KAWAHARA, Kamiina-gun (JP)

(73) Assignee: OLYMPUS CORPORATION, Tokyo (JP)

(21) Appl. No.: 16/995,245

(22) Filed: Aug. 17, 2020

Related U.S. Application Data
(63) Continuation of application No. PCT/JP2018/006156, filed on Feb. 21, 2018.

(51) Int. Cl. G02B 23/24; G02B 23/26; H01S 5/022

(52) U.S. Cl. CPC G02B 23/2453; G02B 23/2476; H01S 5/18305; H01S 5/02284; G02B 23/26

(57) ABSTRACT

An optical module for endoscope includes an optical element, a wiring board on which the optical element is arranged, and a sealing member including a first recess, the optical element being housed in the first recess and hermetically sealed by a periphery of an opening of the first recess being bonded onto the wiring board with a bonding member composed of glass or low melting point metal, wherein an optical waveguide, composed of glass, that penetrates the sealing member or the wiring board and configures an optical path of an optical signal of the optical element is formed in the sealing member or the wiring board.

This application is a continuation application of PCT/JP2018/006156 filed on Feb. 21, 2018, the entire contents of which are incorporated herein by this reference.

### BACKGROUND OF THE INVENTION

### 1. Field of the Invention

The present invention relates to an optical module for endoscope including an optical element, a wiring board and a sealing member, an endoscope including the optical module for endoscope, and a manufacturing method of the optical module for endoscope that is easy to manufacture.

### 2. Description of the Related Art

An endoscope has an image pickup apparatus including an image pickup device such as a CCD at a distal end portion of an elongated insertion portion. Image pickup devices with a high number of pixels have been examined to be used for endoscopes in recent years. An image pickup apparatus using such an image pickup device with a high number of pixels results in increasing a quantity of signals transmitted from the image pickup device to a signal processing apparatus. Therefore, optical signal transmission by optical signals via an optical fiber is preferred to electric signal transmission by electric signals via a metal wire. For the optical signal transmission, an E/O-type optical module (electro-optic converter) which converts an electric signal into an optical signal, and an O/E-type optical module (opto-electric converter) which converts an optical signal into an electric signal are used.

In order to make such an endoscope have a small diameter, it is important to downsize the optical modules. Each optical element is preferably hermetically sealed in order to improve reliability of the optical modules (endoscope).

Each of Japanese Patent Application Laid-Open Publication No. 2005-292739 and Japanese Patent Application Laid-Open Publication No. 2012-160526 discloses an optical module in which an optical element is mounted on a transparent substrate with a recessed portion (recess) and is hermetically sealed in the recessed portion.

Japanese Patent Application Laid-Open Publication No. 2007-206337 discloses an optical module including a lid member which is fitted into a support member in which an optical element is mounted and hermetically seals the optical element, and a lens-equipped and transparent optical fiber connector.

Japanese Patent Application Laid-Open Publication No. 2004-264505 discloses an optical module in which an optical element and an optical fiber are optically coupled with an optical waveguide arranged in a block. The optical waveguide is a separate member from the block, and is arranged, for example, by providing a groove in the block and embedding a transparent member in the groove.

Japanese Patent Application Laid-Open Publication No. 9-311237 discloses a method of producing an optical waveguide inside glass using a femtosecond laser.

### SUMMARY OF THE INVENTION

An optical module for endoscope of an embodiment includes: an optical element; a wiring board on which the optical element is arranged; and a sealing member including a first recess, the optical element being housed in the first recess and hermetically sealed by a periphery of an opening of the first recess being bonded onto the wiring board with a bonding member composed of glass or low melting point metal, wherein an optical waveguide, composed of glass, that penetrates the sealing member or the wiring board and configures an optical path of an optical signal of the optical element is formed in the sealing member or the wiring board.

An endoscope of another embodiment includes an optical module for endoscope, and the optical module for endoscope includes: an optical element; a wiring board on which the optical element is arranged; and a sealing member including a first recess, the optical element being housed in the first recess and hermetically sealed by a periphery of an opening of the first recess being bonded onto the wiring board with a bonding member composed of glass or low melting point metal, wherein an optical waveguide, composed of glass, that penetrates the sealing member or the wiring board and configures an optical path of an optical signal of the optical element is formed in the sealing member or the wiring board.

A manufacturing method of an optical module for endoscope of another embodiment includes: preparing a wiring board; preparing a sealing member including a first recess; arranging an optical element on the wiring board; hermetically sealing the optical element housed in the first recess by bonding a periphery of an opening of the first recess of the sealing member onto the wiring board with a bonding member composed of glass or low melting point metal; and forming an optical waveguide, composed of glass, that configures an optical path of an optical signal by a laser modification method when preparing the sealing member or the wiring board.

### BRIEF DESCRIPTION OF THE DRAWINGS

FIG. 1 is a perspective view of an optical module of a first embodiment;

FIG. 2 is a sectional view, taken along the II-II line in FIG. 1, of the optical module of the first embodiment;

FIG. 3 is an exploded view of the optical module of the first embodiment;

FIG. 4 is a flowchart for explaining a manufacturing method of the optical module of the first embodiment;

FIG. 5 is an example of a sealing member of the optical module of the first embodiment;

FIG. 6 is an example of the sealing member of the optical module of the first embodiment;

FIG. 7 is an example of the sealing member of the optical module of the first embodiment;

FIG. 8 is an example of the sealing member of the optical module of the first embodiment;

FIG. 9 is a flowchart for explaining a manufacturing method of the sealing member of the optical module of the first embodiment;

FIG. 10 is a sectional view for explaining the manufacturing method of the sealing member of the optical module of the first embodiment;

FIG. 11 is an exploded sectional view of an optical module of a second embodiment;

FIG. 12 is a sectional view for explaining a manufacturing method of a sealing member of the optical module of the second embodiment;

FIG. 13 is a sectional view of an optical module of a third embodiment;

FIG. 14 is a sectional view of an optical module of a fourth embodiment;

FIG. 15 is a sectional view of an optical module of a fifth embodiment;

FIG. 16 is a sectional view of an optical module of a sixth embodiment;

FIG. 17 is a sectional view of an optical module of a seventh embodiment; and

FIG. 18 is a perspective view of an endoscope of an eighth embodiment.

### DETAILED DESCRIPTION OF THE PREFERRED EMBODIMENTS

### First Embodiment

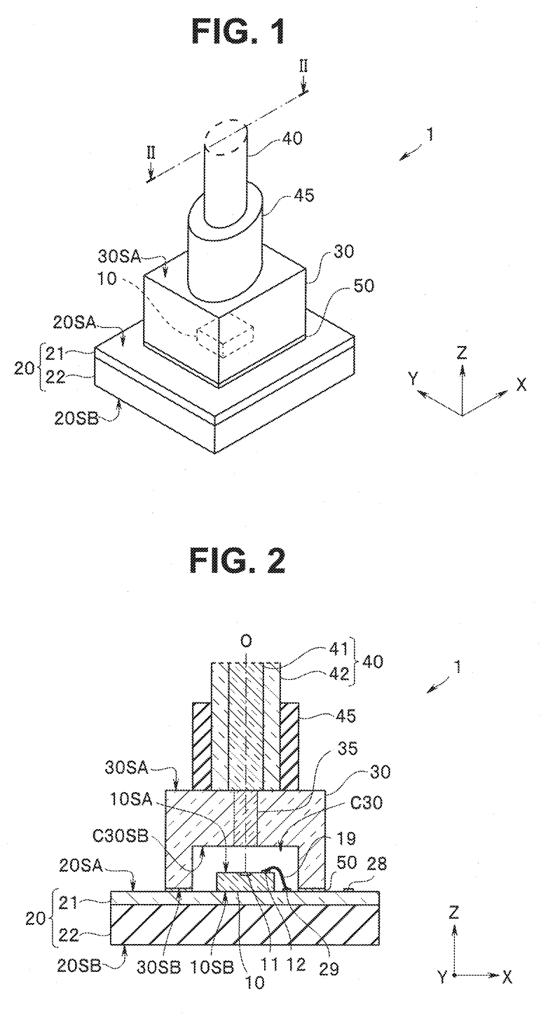

An optical module 1 for endoscope (hereinafter also called “optical module 1”) of a first embodiment is described using FIG. 1 to FIG. 3.

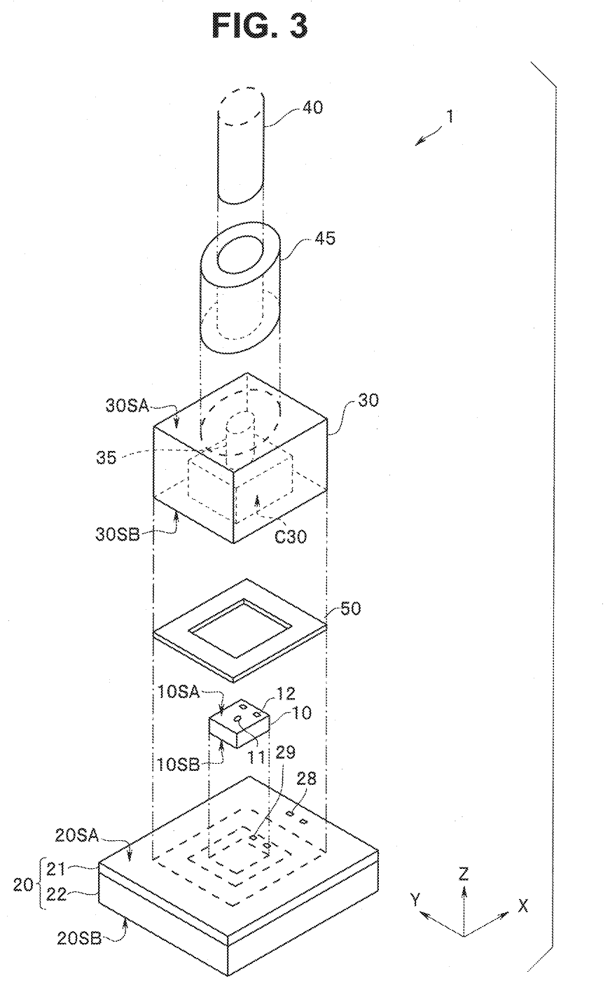

Note that in the following description, drawings based on respective embodiments are schematic and relations between thicknesses and widths of respective portions, ratios among thicknesses of respective portions, and the like are different from those for actual portions and that portions different in relation in dimension and ratio are occasionally contained among drawings. Some components are occasionally omitted in terms of being illustrated and/or being given numerals. For example, in FIG. 3, bonding wires 19 are not illustrated.

An endoscope 9 includes an image pickup portion (not shown) including an image pickup device, and the optical module 1, in a distal end portion 9A (see FIG. 18). The optical module 1 is a very small-sized E/O module (electro-optic converter) which converts an electric signal outputted by the image pickup portion into an optical signal and transmits the optical signal. The optical module 1 includes an optical element 10, a wiring board 20 and a sealing member 30.

The optical element 10 is a light-emitting element having a light-emitting surface 10SA and a back surface 10SB on an opposite side to the light-emitting surface 10SA. The optical element 10 is a vertical cavity surface emitting laser (VCSEL) having a light-emitting portion 11 which outputs an optical signal. The optical element 10 very small-sized with 250 μm×250 μm of dimensions in plan view has the light-emitting portion 11 with 10 μm of diameter, and external electrodes 12 each having 70 μm of diameter connected to the light-emitting portion 11, on the light-emitting surface 10SA.

The wiring board 20 has a first principal surface 20SA and a second principal surface 20SB on an opposite side to the first principal surface 20SA. The first principal surface 20SA is composed of glass, for example, silica glass. The wiring board 20 has, as a base, a stacked plate of a glass substrate 21 configuring the first principal surface 20SA and a support substrate 22 configuring the second principal surface 20SB.

The optical element 10 is arranged on the first principal surface 20SA of the wiring board 20. The external electrodes 12 of the optical element 10 are connected to bonding electrodes 29 on the first principal surface 20SA with the bonding wires 19. The bonding electrodes 29 are connected to interconnecting electrodes 28 on the first principal surface 20SA with not-shown wires.

The sealing member (glass cap) 30 composed of glass has a third principal surface 30SA and a fourth principal surface 30SB on an opposite side to the third principal surface 30SA. A first recess (recessed portion) C30 having an opening on the fourth principal surface 30SB is formed in the sealing member 30. As to the sealing member 30, a periphery of the opening of the first recess C30 on the fourth principal surface 30SB is bonded onto the first principal surface 20SA of the wiring board 20 with low melting point glass 50 which is a bonding member. The optical element 10 arranged on the first principal surface 20SA is housed and hermetically sealed in the first recess C30.

A ferrule 45 is arranged on the third principal surface 30SA of the sealing member 30, and a distal end portion of an optical fiber 40 is inserted into the ferrule 45. In other words, the optical fiber 40 is arranged at a position closer to the third principal surface 30SA of the sealing member 30 than to the fourth principal surface 30SB.

The optical fiber 40 which transmits an optical signal is composed of, for example, a core 41, with 62 μm of diameter, which transmits the optical signal and a cladding 42, with 125 μm of diameter, covering an outer periphery of the core 41.

An optical waveguide (hereinafter called “waveguide”) 35 composed of glass and configuring an optical path of an optical signal is formed in the sealing member 30. While the whole sealing member 30 is configured of glass, the sealing member only has to be glass at least at the waveguide 35 and a peripheral region of the waveguide 35 as mentioned later, and the other region may be another material, for example, silicon. The waveguide 35 penetrates a bottom surface C30SB of the first recess C30 and the third principal surface 30SA of the sealing member 30. The waveguide 35 is formed by changing a refractive index of a part of the glass of the sealing member 30 by a laser modification method.

Since the optical element 10 is hermetically sealed in the first recess C30 of the sealing member 30, the optical module 1 is high in reliability. Note that the sealing member 30 is an optical path of an optical signal even when a waveguide is not formed. The sealing member 30 in which the waveguide 35 is formed is still higher in transmission efficiency than a sealing member in which a waveguide is not formed. The waveguide 35 is easy to manufacture since the waveguide 35 is formed by modifying the sealing member 30. The first recess C30 is high in hermetic sealability and has higher reliability since another material such as an adhesive agent is not arranged at a periphery of the waveguide 35, in other words, all the components configuring a sealed space are composed of glass.

### <Manufacturing Method of Optical Module for Endoscope>

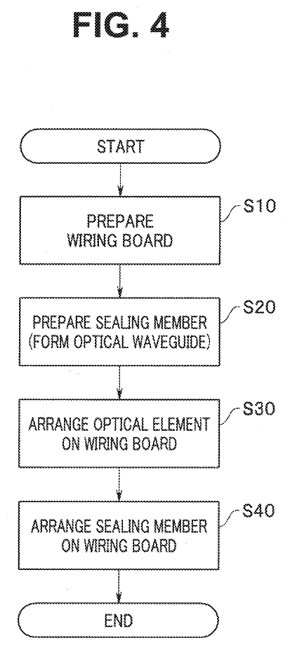

A manufacturing method of the optical module 1 is described along a flowchart of FIG. 4.

### <Step S10> Wiring Board Preparing Step

The glass substrate 21 and the support substrate 22 are stacked to prepare the wiring board 20. The bonding electrodes 29 and the interconnecting electrodes 28 are arranged on the first principal surface 20SA of the wiring board 20. The interconnecting electrodes 28 may be arranged on the second principal surface 20SB via penetration wires.

The base of the wiring board 20 may be the sole glass substrate 21 such as a quartz glass plate. The base of the wiring board 20 may be, for example, a ceramic substrate having the first principal surface 20SA coated with a glass layer.

### <Step S20> Sealing Member Preparing Step (Optical Waveguide Forming Step)

The sealing member 30, composed of glass, having the recess C30 is prepared, for example, by bonding a frame portion to a flat plate or integrally through glass molding using a 3D printer. An outer shape of the sealing member 30 may be a cylindrical shape or a polygonal prismatic shape.

As the glass, silica glass, phosphate glass, borate glass, fluoride glass, chloride glass, sulfide glass, or glass obtained by doping any glass of these with Ge or the like is used.

The waveguide 35, composed of glass, penetrating the bottom surface C30SB of the first recess C30 and the third principal surface 30SA of the sealing member 30 is formed by a laser modification method. In order to attain a photoinduced refractive index change, for example, a femtoseconds pulse laser with 10⁵ W/cm² or more of intensity at a focal point is used, a focal position is being moved inside the glass, and thereby, the waveguide (first modification region) 35 in a desired shape is formed.

Energy of the laser for forming the modification region is lower than energy for laser ablation to remove a material and energy of laser irradiation for heating the material, and pulse energy is, for example, 10 nJ to 1 μJ. A frequency of the laser is 100 kHz to 1 MHz, and in particular, a pulse width is 100 femtoseconds to 500 femtoseconds.

For example, laser light (150 femtoseconds of pulse width, 200 kHz of frequency, 800 nm of wavelength, and 600 W of average power) is condensed with a lens, and is being moved from the third principal surface 30SA to the bottom surface C30SB with the focal position being rotated. The waveguide 35, composed of glass, with 20 μm of diameter is thus formed to penetrate the bottom surface C30SB and the third principal surface 30SA of the sealing member 30 and to have a refractive index higher than a periphery by 0.02.

Note that step S20 (sealing member preparing step) may be performed before step S10 (wiring board preparing step) or may be performed after step S30 (optical element arranging step).

### <Step S30> Optical Element Arranging Step

The optical element 10 is arranged on the first principal surface 20SA of the wiring board 20, and the external electrodes 12 and the bonding electrodes 29 are connected with the bonding wires 19.

### <Step S40> Sealing Member Arranging Step

The sealing member 30 is arranged on the wiring board 20, and the optical element 10 is hermetically sealed in the first recess C30. Namely, the third principal surface 30SA, composed of glass, of the sealing member 30 is bonded onto the first principal surface 20SA, composed of glass, of the wiring board 20 with the low melting point glass 50. For example, the sealing member 30 and the wiring board 20 are bonded together by annularly arranging the low melting point glass between the sealing member 30 and the wiring board 20 and allowing the low melting point glass to melt through irradiation with laser light.

Shapes and the like of the sealing member 30 and the waveguide 35 can be variously modified.

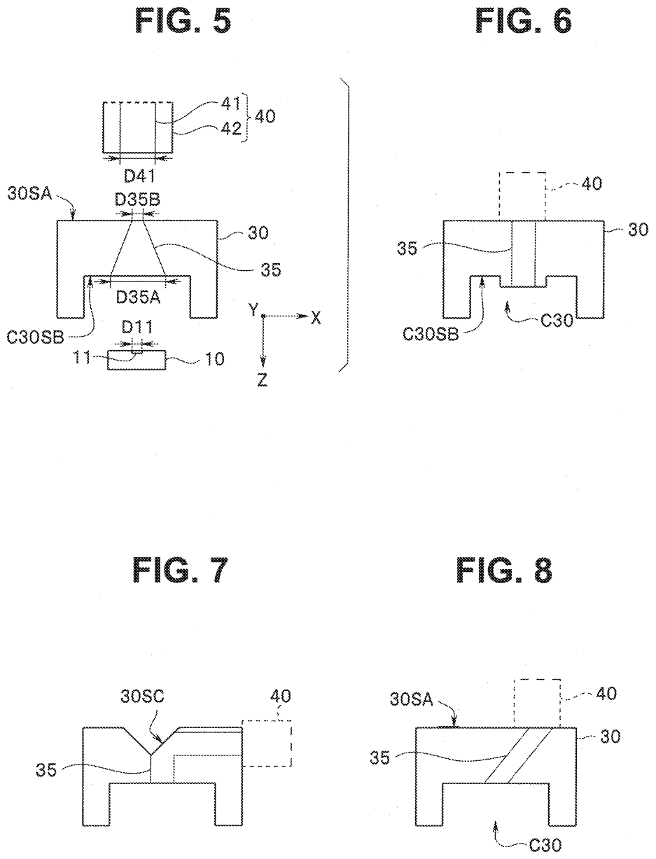

In FIG. 2, diameters of the waveguide 35 in a direction perpendicular to an optical axis O are equal and the outer shape of the waveguide 35 is a cylindrical shape. As shown in FIG. 5, in order to further increase the transmission efficiency of the optical module, the waveguide 35 may have a tapered structure, that is, the outer shape of the waveguide 35 may be a truncated conical shape.

It is preferable in particular that a diameter D35A of an incident surface of the waveguide 35 (light incident portion on the bottom surface C30SB side) is larger than a diameter D41 of the core 41 of the optical fiber 40 and that a diameter D35B of an emission surface of the waveguide 35 (light emission portion on the third principal surface 30SA side) is smaller than the diameter D41 of the core 41 of the optical fiber 40. Needless to say, the diameter D35A is preferably larger than a diameter D11 of the light-emitting portion 11 on the light-emitting surface of the optical element 10.

The sealing member 30 shown in FIG. 6 has a projecting portion on the bottom surface C30SB of the first recess C30, and the waveguide 35 is formed to reach the projecting portion. Since in an optical module having the sealing member, a distance between the light-emitting surface and the waveguide 35 can be made small without bonding wires being in contact with the bottom surface C30SB, the transmission efficiency of the optical module is higher.

In the sealing member 30 shown in FIG. 7, the waveguide 35 bending is formed, so that the optical axis bends at a reflecting surface 30SC by 90 degrees. This enables the optical fiber 40 to be arranged on a lateral surface of the sealing member 30.

On the reflecting surface 30SC, a reflecting film may be arranged, and a recess configuring the reflecting surface 30SC may be filled with resin or the like.

The waveguide 35 of the sealing member 30 shown in FIG. 8 is inclined relative to the third principal surface 30SA. Even in the case of an optical module in which a plurality of light-emitting elements are arranged in the first recess C30, a plurality of optical fibers can be arranged on the third principal surface 30SA since a plurality of inclined optical waveguides are formed.

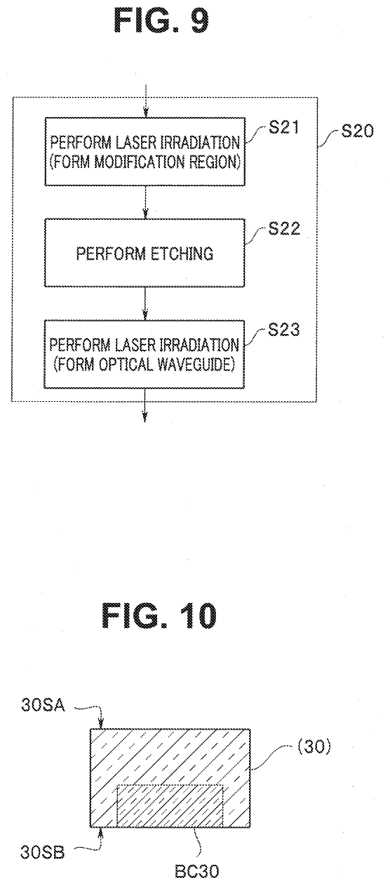

As shown in a flowchart of FIG. 9, in the manufacturing method of the optical module 1, the sealing member preparing step (step S20) preferably further includes a step of forming a first modification region (step S21) and a step of forming the first recess C30 (step S22) before a laser irradiation step of forming the optical waveguide (step S23). In step S21, the first modification region is formed by laser irradiation (laser modification method). In step S22, the first recess C30 is formed by dissolving the first modification region by wet etching.

Namely, as shown in FIG. 10, the sealing member 30 composed of glass is irradiated with laser to form a first modification region BC30. The sealing member 30 is etched with a low concentration hydrofluoric acid solution. An etching speed of the modification region BC30 is 100 times higher than an etching speed of an unmodified region. Therefore, the modification region BC30 is dissolved and the first recess C30 is formed.

Laser irradiation conditions for forming the first modification region BC30 are substantially identical to laser irradiation conditions for forming the waveguide 35. Therefore, the waveguide 35 and the first modification region BC30 can be formed using an identical apparatus. According to the manufacturing method, the sealing member 30 having the first recess C30 is easy to prepare.

### Second Embodiment

Since optical modules 1A to 1F of embodiments described hereafter are similar to the optical module 1 and have identical effects to the effects of the optical module 1, components having identical functions are given identical signs and their description is omitted.

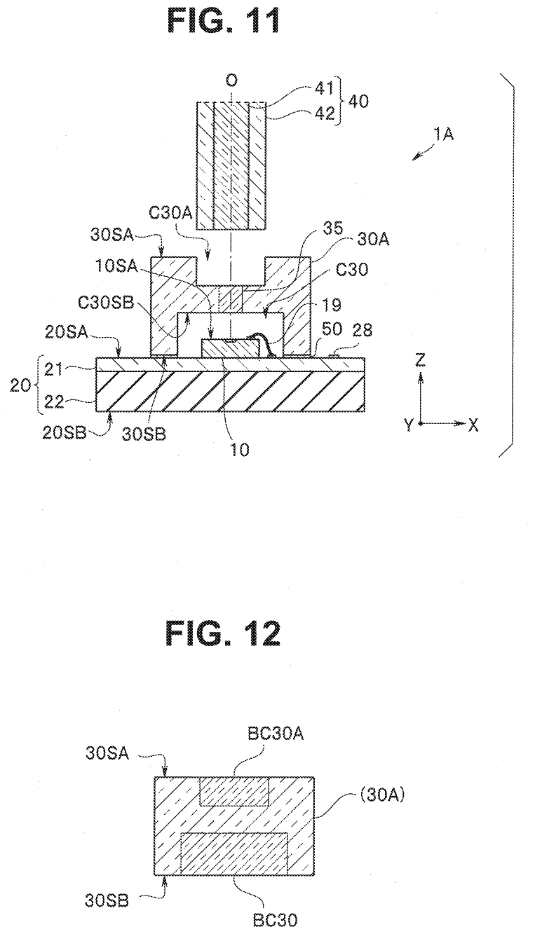

As shown in FIG. 11, a sealing member 30A of an optical module 1A of a second embodiment has, on the third principal surface 30SA, a second recess C30A for positioning of the optical fiber 40. Namely, the optical fiber 40 is defined in terms of a position in a direction perpendicular to the optical axis by being inserted into the second recess C30A.

As to a manufacturing method of the optical module 1A, in the step of forming the first modification region (S21) shown in FIG. 9, a second modification region is formed in the sealing member by laser irradiation under identical conditions to the conditions for forming the first modification region, and in the etching step of forming the first recess (S22), the second recess is simultaneously formed with the first recess.

Namely, as shown in FIG. 12, the sealing member 30A is irradiated with laser to form the first modification region BC30 and a second modification region BC30A (S21). The first modification region BC30 and the second modification region BC30A are etched with a low concentration hydrofluoric acid solution, and thereby, the first recess C30 and the second recess C30A are formed.

The optical module 1A does not need a ferrule. The second recess C30A is formed in the same step for the first recess C30. The optical module 1A is therefore easy to manufacture.

### Third Embodiment

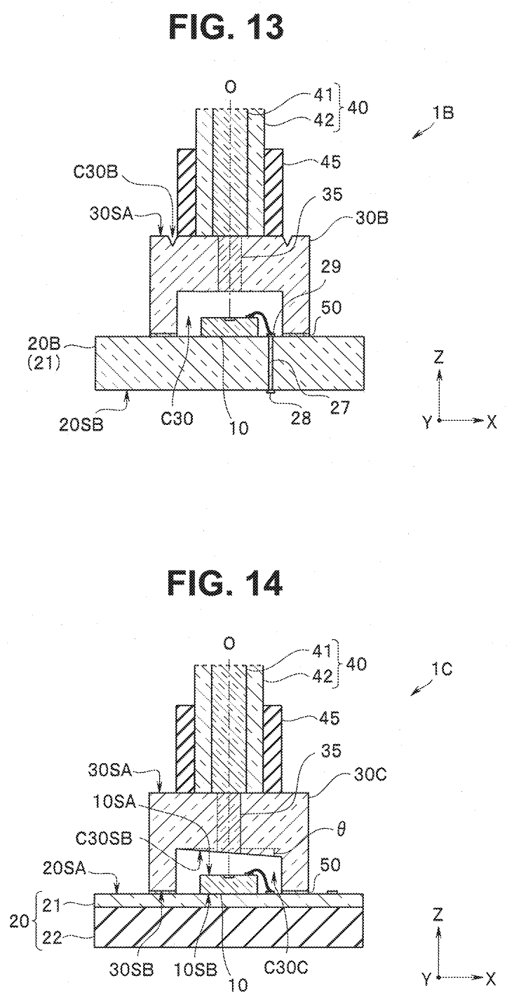

A sealing member 30B of an optical module 1B of a third embodiment shown in FIG. 13 has, on the third principal surface 30SA, a second recess C30B for positioning of the optical fiber 40. The second recess C30B is a ring-like V-shaped groove, for example. Since the ferrule 45 is arranged along an outer periphery of the second recess C30B, the position of the optical fiber 40 in the direction perpendicular to the optical axis is defined.

The second recess C30B is formed by etching the second modification region formed by laser irradiation under identical conditions to the conditions for forming the second recess C30A of the optical module 1A.

Note that a wiring board 20B of the optical module 1B has, as a base, the glass substrate 21 and has penetration wires 27 penetrating the second principal surface 20SB of the wiring board 20B from the first principal surface 20SA. The interconnecting electrodes 28 arranged on the second principal surface 20SB are connected to the bonding electrodes 29 via the penetration wires 27.

### Fourth Embodiment

In an optical module 1C of a fourth embodiment shown in FIG. 14, the bottom surface C30SB of a first recess C30C of a sealing member 30C is inclined relative to the fourth principal surface 30SB. Therefore, the bottom surface C30SB which is an incident surface of the waveguide 35 is inclined relative to the light-emitting surface 10SA of the optical element 10.

Since the optical axis of the optical element 10 and the optical axis of the waveguide 35 are superimposed on each other, there is a concern that multiple reflections between the light-emitting surface 10SA and the incident surface (C30SB) of the waveguide 35 arise to cause noise.

Since in the optical module 1C, the bottom surface C30SB is inclined relative to the light-emitting surface 10SA at an inclination angle θ not less than 2 degrees and not more than 12 degrees, noise can be prevented from arising due to the multiple reflections. The optical module 1C therefore attains high transmission quality.

Note that the first recess C30C in which the bottom surface C30SB is inclined can be easily prepared since a modification region having an inclined surface is formed by a laser modification method and etched.

Note that the optical module 1C may have a second recess for positioning of the optical fiber 40 in the sealing member 30C as in the optical modules 1A and 1B.

### Fifth Embodiment

In the optical modules 1 and 1A to 1C having been described, the whole sealing member is composed of glass, and the optical waveguide penetrating the sealing member is formed. Moreover, the first principal surface, composed of glass, of the wiring board and the sealing member are bonded together with low melting point glass.

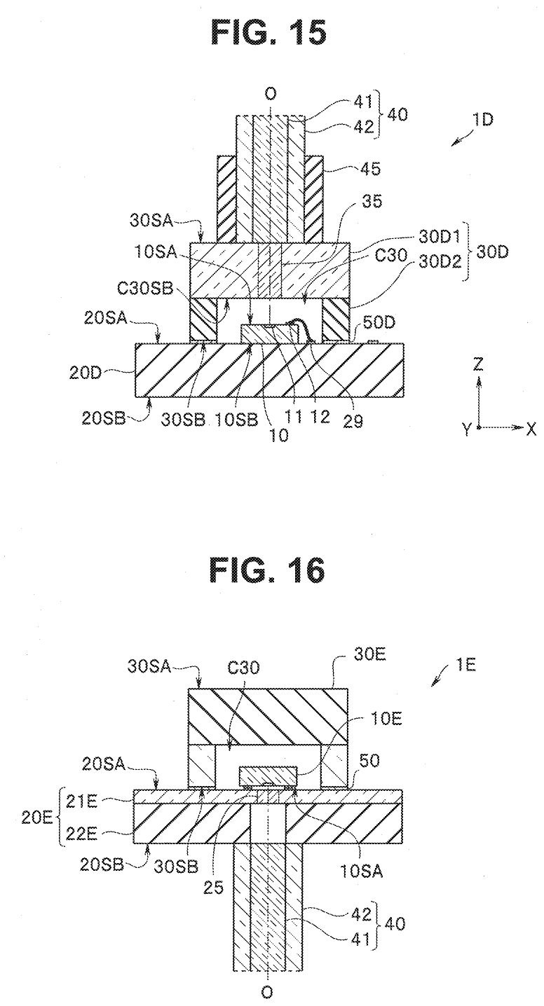

On the contrary, in an optical module 1D of a fifth embodiment shown in FIG. 15, a sealing member 30D is a composite member of a glass plate 30D1 and a frame member 30D2 which is composed of silicon. A wiring board 20D is composed of ceramics.

Metal layers are respectively arranged on the fourth principal surface 30SB of the frame member 30D2 and the first principal surface 20SA of the wiring board 20D. The frame member 30D2 and the wiring board 20D are bonded together with a bonding member 50D composed of low melting point metal such as solder. The optical element 10 arranged on the first principal surface 20SA is housed and hermetically sealed in the first recess C30.

Namely, the sealing member only has to be configured, at least at the waveguide 35 and the peripheral region of the waveguide 35, of glass from which a waveguide can be formed using a laser modification method, and the other region may be configured of another material. The bonding member between the sealing member and the wiring board is not limited to glass.

Note that the optical module 1D may have a second recess for positioning of the optical fiber 40 on the third principal surface 30SA of the sealing member 30D as in the optical modules 1A and 1B. In this case, a region (second modification region) for forming the second recess is also configured of glass.

In the optical module 1D, the bottom surface of the first recess may be inclined relative to the light-emitting surface of the optical element 10 at an inclination angle not less than 2 degrees and not more than 12 degrees as in the optical module 1C. In this case, a region (first modification region) for forming the first recess is preferably configured of glass.

### Sixth Embodiment

In an optical module 1E of a sixth embodiment shown in FIG. 16, the optical fiber 40 is inserted into a ferrule (not shown) arranged on the second principal surface 20SB of a wiring board 20E. Namely, the optical fiber 40 is arranged at a position closer to the second principal surface 20SB than to the first principal surface 20SA.

External electrodes on the light-emitting surface 10SA of an optical element 10E are bonded to bonding electrodes on the first principal surface 20SA of the wiring board 20E, for example, by ultrasound bonding.

A waveguide 25 configuring the optical path of an optical signal penetrates the first principal surface 20SA and the second principal surface 20SB of the wiring board 20E. Namely, the waveguide 25 composed of glass and penetrating the wiring board 20E is formed by a laser modification method. Namely, a base of the wiring board 20E includes a glass substrate 21E, and a support substrate 22E which has a through hole at a region to be the optical path.

Note that a sealing member 30E has an opaque ceramic plate and a frame-like glass member.

### Seventh Embodiment

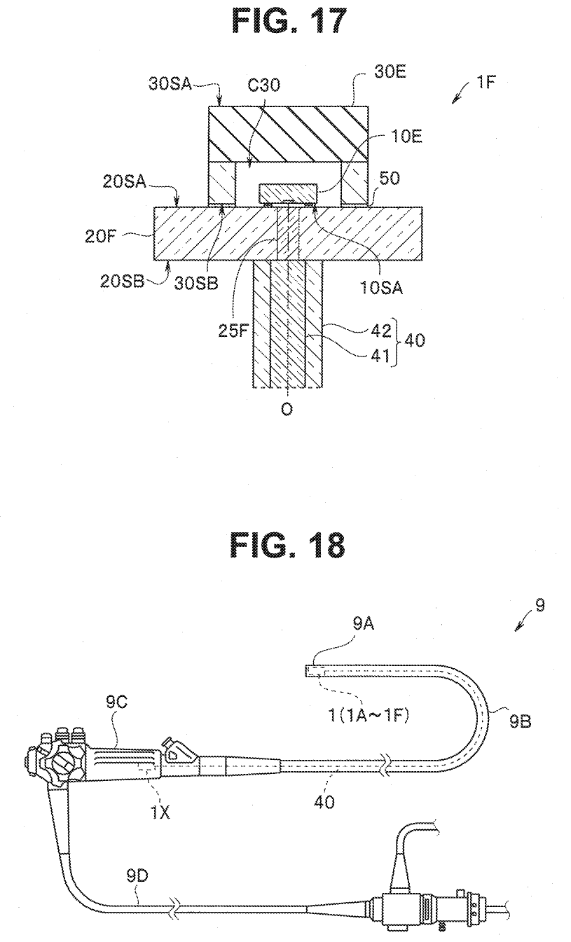

While an optical module 1F of a seventh embodiment shown in FIG. 17 is similar to the optical module 1E, the base of a wiring board 20F is a glass substrate only. Namely, the wiring board does not need a support substrate as long as the wiring board includes a glass substrate that an optical waveguide can be formed in.

The wiring board 20F without a support substrate is thick and an optical signal tends to attenuate. But the optical module 1F is excellent in transmission efficiency since an optical waveguide 25F to be the optical path is formed in the wiring board 20F. The optical module 1F is high in reliability since the optical element 10E is hermetically sealed.

As in the description above, in an optical module of the present invention, an optical waveguide, composed of glass, that penetrates a sealing member or a wiring board and configures an optical path of an optical signal is formed in the sealing member or the wiring board.

### Eighth Embodiment

The endoscope 9 of an eighth embodiment is described. As shown in FIG. 18, the endoscope 9 has the optical module 1 (any of 1A to 1F) at the distal end portion 9A of an insertion portion 9B.

The endoscope 9 includes the insertion portion 9B in which an image pickup portion having an image pickup device with a high number of pixels is arranged at the distal end portion 9A, an operation portion 9C arranged at a proximal end portion of the insertion portion 9B, and a universal cord 9D extending from the operation portion 9C.

An electric signal outputted by the image pickup portion is converted into an optical signal by the E/O-type optical module 1, the optical signal is transmitted to an O/E-type optical module 1X which is arranged in the operation portion 9C and in which an optical element arranged is a PD via the optical fiber 40 and converted again into an electric signal by the optical module 1X, and the electric signal is transmitted via a metal wire. Namely, in the insertion portion 9B having a small diameter, the optical fiber 40 transmits a signal.

Otherwise, the electric signal outputted by the image pickup portion may be transmitted as an electric signal via a metal wire in the insertion portion 9B and be converted into the optical signal by the E/O-type optical module 1 arranged in the operation portion 9C, and the optical signal may be transmitted to the O/E-type optical module 1X which is arranged in an endoscope system main body (not shown) and in which an optical element is a PD via an optical fiber which the universal cord 9D allows insertion of and be converted into the electric signal by the optical module 1X.

Otherwise, the electric signal outputted by the image pickup portion may be converted into the optical signal by the E/O-type optical module 1, be transmitted to the endoscope system main body (not shown) via the optical fiber 40 which the insertion portion 9B, the operation portion 9C and the universal cord 9D allow insertion of, and be converted into the electric signal by the O/E-type optical module 1X which is arranged in the endoscope system main body and in which an optical element is a PD.

As having been described, the optical module 1 (any of 1A to 1F) is high in transmission efficiency due to having the optical waveguide formed by the laser modification method. The optical module 1 is also high in reliability since the optical element 10 is hermetically sealed by the sealing member. The endoscope 9 is therefore high in reliability and easy to manufacture.

Note that while being arranged in the operation portion 9C which has a wide arrangement space, the optical module 1X preferably has an identical configuration to the configuration of the optical module 1 of the present invention. While being a flexible endoscope, the endoscope 9 may be a rigid endoscope. A control signal to the image pickup portion may be converted into an optical signal by the optical module 1 that is arranged in the operation portion 9C, and the optical signal may be converted into an electric signal by the optical module 1X that is arranged in the distal end portion 9A.

In the optical module 1, the optical element 10 is a light-emitting element having the light-emitting portion 11 which outputs an optical signal. It goes without saying that an optical module has similar effects to the effects of the optical module 1 even if the optical element of the optical module is a light receiving element, such as a photodiode, having a light receiving portion into which an optical signal is inputted.

Namely, an optical element of an optical module of the present invention only has to have a light-emitting portion which outputs an optical signal or a light receiving portion into which an optical signal is inputted, and external electrodes connected to the light-emitting portion or the light receiving portion.

The present invention is not limited to the embodiments mentioned above but various modifications, combinations and applications are possible without departing from the scope of the invention.

What is claimed is:

1. An optical module for endoscope, comprising:
an optical element;
a wiring board on which the optical element is arranged; and
a sealing member including a first recess, the optical element being housed in the first recess and hermetically sealed by a periphery of an opening of the first recess being bonded onto the wiring board with a bonding member composed of glass or low melting point metal, wherein
an optical waveguide, composed of glass, that penetrates the sealing member or the wiring board and configures an optical path of an optical signal of the optical element is formed in the sealing member or the wiring board.

2. The optical module for endoscope of claim 1, wherein
the sealing member includes a third principal surface and a fourth principal surface on an opposite side to the third principal surface and includes the opening of the first recess on the fourth principal surface,
a distal end portion of an optical fiber that transmits the optical signal passing through the optical waveguide is arranged at a position closer to the third principal surface than to the fourth principal surface, and
the optical waveguide penetrating a bottom surface of the first recess and the third principal surface is formed in the sealing member.

3. The optical module for endoscope of claim 2, wherein the sealing member is composed of glass.

4. The optical module for endoscope of claim 2, wherein the sealing member is a composite member of a glass plate and a frame member composed of silicon.

5. The optical module for endoscope of claim 2, wherein a second recess for positioning of the optical fiber is on the third principal surface of the sealing member.

6. The optical module for endoscope of claim 5, wherein the second recess is a ring-like V-shaped groove.

7. The optical module for endoscope of claim 1, wherein a bottom surface of the first recess is inclined relative to a light-emitting surface of the optical element at an inclination angle not less than 2 degrees and not more than 12 degrees.

8. The optical module for endoscope of claim 1, wherein
the wiring board includes a first principal surface that is bonded onto the sealing member, and a second principal surface on an opposite side to the first principal surface,
a distal end portion of the optical fiber that transmits the optical signal passing through the optical waveguide is arranged at a position closer to the second principal surface than to the first principal surface, and
the optical path of the optical signal penetrates the first principal surface and the second principal surface, and the optical waveguide is formed in the wiring board.

9. The optical module for endoscope of claim 8, wherein the wiring board is composed of glass.

10. The optical module for endoscope of claim 8, wherein the wiring board includes a glass substrate, and a support substrate having a through hole at a region which is the optical path.

11. The optical module for endoscope of claim 1, wherein the optical waveguide is formed by a laser modification method.

12. An endoscope including an optical module for endoscope, the optical module for endoscope comprising:
an optical element;
a wiring board on which the optical element is arranged; and
a sealing member including a first recess, the optical element being housed in the first recess and hermetically sealed by a periphery of an opening of the first recess being bonded onto the wiring board with a bonding member composed of glass or low melting point metal, wherein
an optical waveguide, composed of glass, that penetrates the sealing member or the wiring board and configures an optical path of an optical signal of the optical element is formed in the sealing member or the wiring board.

13. A manufacturing method of an optical module for endoscope, comprising:
preparing a wiring board;
preparing a sealing member including a first recess;
arranging an optical element on the wiring board;
hermetically sealing the optical element housed in the first recess by bonding a periphery of an opening of the first recess of the sealing member onto the wiring board with a bonding member composed of glass or low melting point metal; and
forming an optical waveguide, composed of glass, that configures an optical path of an optical signal by a laser modification method when preparing the sealing member or the wiring board.

14. The manufacturing method of an optical module for endoscope of claim 13, wherein
the optical waveguide that penetrates a bottom surface of the first recess of the sealing member and a third principal surface on an opposite side to the bottom surface is formed when preparing the sealing member, the method comprising:
before forming the optical waveguide,
forming a first modification region composed of glass in the sealing member by the laser modification method; and
dissolving the first modification region by wet etching to form the first recess.

15. The manufacturing method of an optical module for endoscope of claim 14, wherein
when forming the first modification region, a second modification region composed of glass is formed in the sealing member by the laser modification method under an identical condition to a condition for forming the first modification region, and
when forming the first recess, a second recess for positioning of an optical fiber that transmits an optical signal is formed by wet etching of the second modification region simultaneously to forming the first recess.

16. The manufacturing method of an optical module for endoscope of claim 13, wherein at least one of the wiring board and the sealing member is composed of glass.
